(19) United States
(12) Patent Application Publication
(10) Pub. No.: US 2023/0098645 A1
(43) Pub. Date: Mar. 30, 2023

(54) METHOD AND SYSTEM FOR UPSCALING RESERVOIR MODELS USING UPSCALING GROUPS

(71) Applicant: SAUDI ARABIAN OIL COMPANY, Dhahran (SA)

(72) Inventors: Jubril Oluwa, Dhahran (SA); Ali Essa Al-Mahfoudh, Al-Qatif (SA); Abdullah Hamidi, Al Khobar (SA)

(73) Assignee: SAUDI ARABIAN OIL COMPANY, Dhahran (SA)

(21) Appl. No.: 17/484,640

(22) Filed: Sep. 24, 2021

(51) Int. Cl. G06T 17/05; E21B 47/12; G06F 30/20

(52) U.S. Cl. CPC G06T 17/05; E21B 47/138; G06F 30/20; E21B 2200/20

(57) ABSTRACT

A method may obtain static reservoir data for a grid model. The method may further include determining, using the static reservoir data, dynamic reservoir data for the grid model. The method may further include determining various storage capacities and various flow capacities for various model layers within the grid model using the static reservoir data. The method may further include determining various upscaling groups among the model layers based on the flow capacities and the storage capacities. The method may further include generating up scaled static data using the upscaling groups, the static reservoir data, and the grid model. The method may further include generating upscaled dynamic data using the upscaling groups, the dynamic reservoir data, and the grid model. The method may further include performing a reservoir simulation using a coarsened grid model including the upscaled static data and the upscaled dynamic data.

### BACKGROUND

In a coarsened model, properties for various cells may be averaged in a process called upscaling. However, if not applied properly, upscaling may provide a solution in the coarsened model that may lose accuracy as details are lost in the averaging process, especially where coarsening is applied to highly influential grid cells. Thus, accurate simulations may require a coarsened model that reduces the computational time to a reasonable speed while also preserving relevant physical relationships in the underlying data.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to a method that includes obtaining, by a computer processor, static reservoir data for a grid model. The method further includes determining, by the computer processor and using the static reservoir data, dynamic reservoir data for the grid model. The method further includes determining, by the computer processor, various storage capacities and various flow capacities for various model layers within the grid model using the static reservoir data. The method further includes determining, by the computer processor, various upscaling groups among the model layers based on the flow capacities and the storage capacities. The method further includes generating, by the computer processor, upscaled static data using the upscaling groups, the static reservoir data, and the grid model. The method further includes generating, by the computer processor, upscaled dynamic data using the upscaling groups, the dynamic reservoir data, and the grid model. The method further includes performing, by the computer processor, a reservoir simulation using a coarsened grid model including the upscaled static data and the upscaled dynamic data.

In general, in one aspect, embodiments relate to a system that includes a wellhead coupled to a wellbore and a reservoir simulator. The reservoir simulator includes a computer processor. The reservoir simulator obtains static reservoir data for a grid model. The reservoir simulator determines, using the static reservoir data, dynamic reservoir data for the grid model. The reservoir simulator determines various storage capacities and various flow capacities for various model layers within the grid model using the static reservoir data. The reservoir simulator determines various upscaling groups among the model layers based on the flow capacities and the storage capacities. The reservoir simulator generates upscaled static data using the upscaling groups, the static reservoir data, and the reservoir model. The reservoir simulator generates upscaled dynamic data using the upscaling groups, the dynamic reservoir data, and the grid model. The reservoir simulator performs a reservoir simulation using a coarsened grid model including the upscaled static data, the upscaled dynamic data, and wellhead data regarding the wellhead.

In general, in one aspect, embodiments relate to a non-transitory computer readable medium storing instructions executable by a computer processor. The instructions obtain static reservoir data for a grid model. The instructions further determine, using the static reservoir data, dynamic reservoir data for the grid model. The instructions further determine various storage capacities and various flow capacities for various model layers within the grid model using the static reservoir data. The instructions further determine various upscaling groups among the model layers based on the flow capacities and the storage capacities. The instructions further generate upscaled static data using the upscaling groups, the static reservoir data, and the grid model. The instructions further generate upscaled dynamic data using the upscaling groups, the dynamic reservoir data, and the grid model. The instructions further perform a reservoir simulation using a coarsened grid model including the upscaled static data and the upscaled dynamic data.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIGS. 1, 2A, and 2B show systems in accordance with one or more embodiments.

FIG. 3 shows a flowchart in accordance with one or more embodiments.

FIGS. 4, 5, 6A, and 6B show examples in accordance with one or more embodiments.

FIG. 7 shows a computer system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In general, embodiments of the disclosure include systems and methods for using upscaling groups to determine upscaled static data and upscaled dynamic data for a reservoir grid model. In particular, static reservoir data may include values for porosity, permeability, and water saturation, while dynamic reservoir data may include values for residual saturations and relative permeabilities. While static reservoir data may describe underlying physical properties, dynamic reservoir data may be dependent on one or more well operations associated with a reservoir, such as production operations, stimulation operations, and enhancement operations using injections wells. Thus, upscaling dynamic reservoir data may pose distinct challenges from upscaling static data. As such, some embodiments determine various upscaling groups that provide upscaling tiers for determining weighted data for different model layers of a grid model.

Furthermore, upscaling groups may be determined using storage capacities and flow capacities for a particular reservoir. Static reservoir data may be used to determine storage capacity data and flow capacity data for individual model layers. Afterwards, different model layers may be assigned to different upscaling groups based the storage capacity data and flow capacity data (e.g., using ratio values between them). From the resulting upscaling groups, different types of upscaling operations may be applied to model layers within a respective group to determine upscaled data. For example, Lorenz coefficients may be used to upscale static reservoir data in a particular upscaling group, while pseudo functions (e.g., based on a vertical equilibrium method) may be used to upscale dynamic reservoir data.

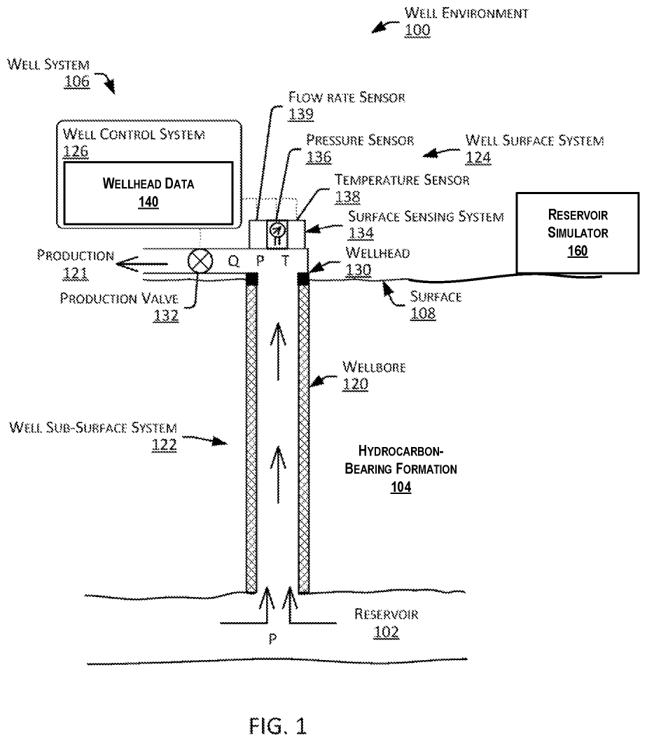

Turning to FIG. 1, FIG. 1 shows a schematic diagram in accordance with one or more embodiments. As shown in FIG. 1, FIG. 1 illustrates a well environment (100) that includes a hydrocarbon reservoir (“reservoir”) (102) located in a subsurface hydrocarbon-bearing formation (104) and a well system (106). The hydrocarbon-bearing formation (104) may include a porous or fractured rock formation that resides underground, beneath the earth's surface (“surface”) (108). In the case of the well system (106) being a hydrocarbon well, the reservoir (102) may include a portion of the hydrocarbon-bearing formation (104). The hydrocarbon-bearing formation (104) and the reservoir (102) may include different layers of rock having varying properties, such as varying degrees of permeability, porosity, and resistivity. In the case of the well system (106) being operated as a production well, the well system (106) may facilitate the extraction of hydrocarbons (or “production”) from the reservoir (102).

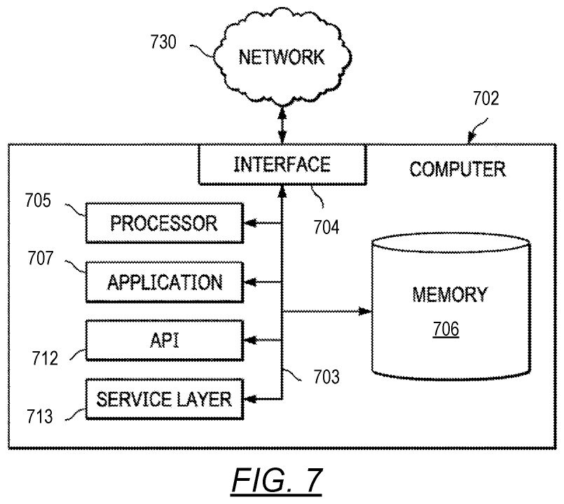

In some embodiments, the well system (106) includes a wellbore (120), a well sub-surface system (122), a well surface system (124), and a well control system (126). The control system (126) may control various operations of the well system (106), such as well production operations, well completion operations, well maintenance operations, and reservoir monitoring, assessment and development operations. In some embodiments, the control system (126) includes a computer system that is the same as or similar to that of computer system (702) described below in FIG. 7 and the accompanying description.

The wellbore (120) may include a bored hole that extends from the surface (108) into a target zone of the hydrocarbon-bearing formation (104), such as the reservoir (102). An upper end of the wellbore (120), terminating at or near the surface (108), may be referred to as the “up-hole” end of the wellbore (120), and a lower end of the wellbore, terminating in the hydrocarbon-bearing formation (104), may be referred to as the “down-hole” end of the wellbore (120). The wellbore (120) may facilitate the circulation of drilling fluids during drilling operations, the flow of hydrocarbon production (“production”) (121) (e.g., oil and gas) from the reservoir (102) to the surface (108) during production operations, the injection of substances (e.g., water) into the hydrocarbon-bearing formation (104) or the reservoir (102) during injection operations, or the communication of monitoring devices (e.g., logging tools) into the hydrocarbon-bearing formation (104) or the reservoir (102) during monitoring operations (e.g., during in situ logging operations).

In some embodiments, during operation of the well system (106), the control system (126) collects and records wellhead data (140) for the well system (106). The wellhead data (140) may include, for example, a record of measurements of wellhead pressure (P_{wh}) (e.g., including flowing wellhead pressure), wellhead temperature (T_{wh}) (e.g., including flowing wellhead temperature), wellhead production rate (Q_{wh}) over some or all of the life of the well (106), and water cut data. In some embodiments, the measurements are recorded in real-time, and are available for review or use within seconds, minutes or hours of the condition being sensed (e.g., the measurements are available within 1 hour of the condition being sensed). In such an embodiment, the wellhead data (140) may be referred to as “real-time” wellhead data (140). Real-time wellhead data (140) may enable an operator of the well (106) to assess a relatively current state of the well system (106), and make real-time decisions regarding development of the well system (106) and the reservoir (102), such as on-demand adjustments in regulation of production flow from the well.

In some embodiments, the well surface system (124) includes a wellhead (130). The wellhead (130) may include a rigid structure installed at the “up-hole” end of the wellbore (120), at or near where the wellbore (120) terminates at the Earth's surface (108). The wellhead (130) may include structures for supporting (or “hanging”) casing and production tubing extending into the wellbore (120). Production (121) may flow through the wellhead (130), after exiting the wellbore (120) and the well sub-surface system (122), including, for example, the casing and the production tubing. In some embodiments, the well surface system (124) includes flow regulating devices that are operable to control the flow of substances into and out of the wellbore (120). For example, the well surface system (124) may include one or more production valves (132) that are operable to control the flow of production (134). For example, a production valve (132) may be fully opened to enable unrestricted flow of production (121) from the wellbore (120), the production valve (132) may be partially opened to partially restrict (or “throttle”) the flow of production (121) from the wellbore (120), and production valve (132) may be fully closed to fully restrict (or “block”) the flow of production (121) from the wellbore (120), and through the well surface system (124).

Keeping with FIG. 1, in some embodiments, the well surface system (124) includes a surface sensing system (134). The surface sensing system (134) may include sensors for sensing characteristics of substances, including production (121), passing through or otherwise located in the well surface system (124). The characteristics may include, for example, pressure, temperature and flow rate of production (121) flowing through the wellhead (130), or other conduits of the well surface system (124), after exiting the wellbore (120).

In some embodiments, the surface sensing system (134) includes a surface pressure sensor (136) operable to sense the pressure of production (151) flowing through the well surface system (124), after it exits the wellbore (120). The surface pressure sensor (136) may include, for example, a wellhead pressure sensor that senses a pressure of production (121) flowing through or otherwise located in the wellhead (130). In some embodiments, the surface sensing system (134) includes a surface temperature sensor (138) operable to sense the temperature of production (151) flowing through the well surface system (124), after it exits the wellbore (120). The surface temperature sensor (138) may include, for example, a wellhead temperature sensor that senses a temperature of production (121) flowing through or otherwise located in the wellhead (130), referred to as “wellhead temperature” (T_{wh}). In some embodiments, the surface sensing system (134) includes a flow rate sensor (139) operable to sense the flow rate of production (151) flowing through the well surface system (124), after it exits the wellbore (120). The flow rate sensor (139) may include hardware that senses a flow rate of production (121) (Q_{wh}) passing through the wellhead (130).

In some embodiments, the well system (106) includes a reservoir simulator (160). For example, the reservoir simulator (160) may include hardware and/or software with functionality for generating one or more reservoir models regarding the hydrocarbon-bearing formation (104) and/or performing one or more reservoir simulations. For example, the reservoir simulator (160) may store well logs and data regarding core samples for performing simulations. A reservoir simulator may further analyze the well log data, the core sample data, seismic data, and/or other types of data to generate and/or update the one or more reservoir models. While the reservoir simulator (160) is shown at a well site, embodiments are contemplated where reservoir simulators are located away from well sites. In some embodiments, the reservoir simulator (160) may include a computer system that is similar to the computer system (702) described below with regard to FIG. 7 and the accompanying description.

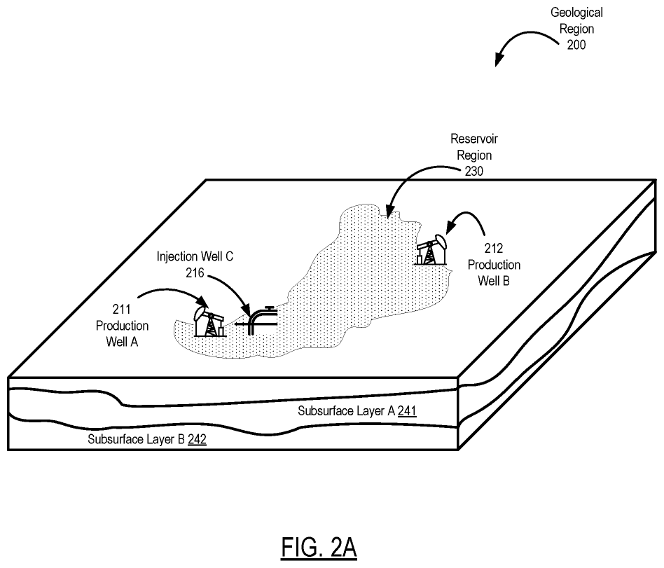

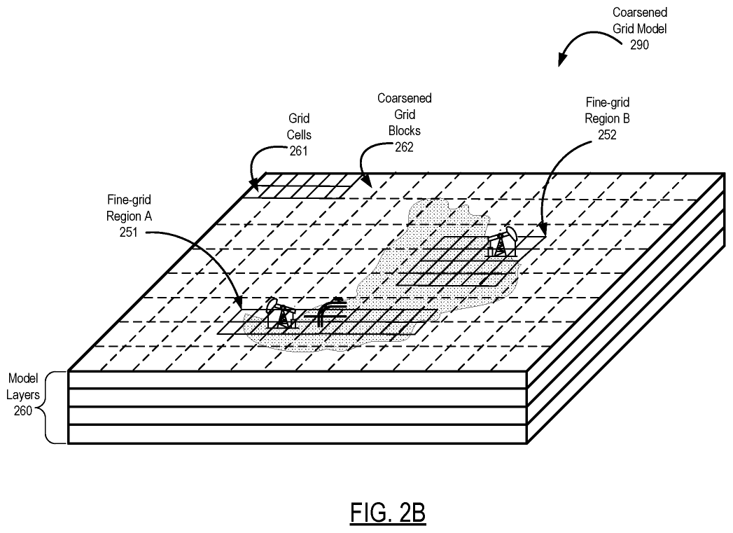

Turning to FIG. 2A, FIG. 2A shows a schematic diagram in accordance with one or more embodiments. As illustrated in FIG. 2A, FIG. 2A shows a geological region (200) that may include one or more reservoir regions (e.g., reservoir region (230)) with various production wells (e.g., production well A (211), production well (212)). For example, a production well may be similar to the well system (106) described above in FIG. 1 and the accompanying description. Likewise, a reservoir region may also include one or more injection wells (e.g., injection well C (216)) that include functionality for enhancing production by one or more neighboring production wells. As shown in FIG. 2A, wells may be disposed in the reservoir region (230) above various subsurface layers (e.g., subsurface layer A (241), subsurface layer B (242)), which may include hydrocarbon deposits. In particular, production data and/or injection data may exist for a particular well, where production data may include data that describes production or production operations at a well, such as wellhead data (140) described in FIG. 1 and the accompanying description.

Turning to FIG. 2B, FIG. 2B shows a schematic diagram in accordance with one or more embodiments. As illustrated in FIG. 2B, FIG. 2B shows a coarsened grid model (290) that corresponds to the geological region (200) from FIG. 2A. More specifically, the coarsened grid model (290) includes grid cells (261) that may refer to an original cell of a grid model as well as coarsened grid blocks (262) that may refer to an amalgamation of original cells of the grid model. For example, a grid cell may be the case of a 1×1 block, where coarsened grid blocks may be of sizes 2×2, 4×4, 8×8, etc. Both the grid cells (261) and the coarsened grid blocks (262) may correspond to columns for multiple model layers (260) within the coarsened grid model (290).

In some embodiments, a grid model may include static reservoir properties and dynamic reservoir properties. For example, static reservoir properties may include properties such as grid cell thickness (H), porosity (Phi), permeability (K), water saturation (Sw), and net-to-gross (NTG) values (i.e., a net-to-gross value may be the fraction of reservoir volume occupied by hydrocarbon-producing rocks). On the other hand, dynamic reservoir properties may include residual saturation values that describe various reservoir properties with respective to various well operations (such as a production operation or a reservoir stimulation operation). For example, residual oil saturation (Sor) may describe a fraction of a pore volume occupied by oil after an oil displacement process (e.g., production or stimulation operation). Thus, residual oil saturation may indicate a final oil recovery from a reservoir region using a specific oil displacement process. Likewise, residual oil saturation may be defined according to a predetermined displacement method (e.g., based on a type of displacement method, volume of the affected reservoir region, one or more fluid directions, and displacement fluid velocity). Residual oil saturation may be expressed as a ratio of immobile residual oil volume divided by an effective porosity for the reservoir region. Besides residual oil saturation, other types of residual saturation values include residual water saturation (Swr), critical water saturation (Swc), critical oil saturation (Soc), and residual gas saturation (Sgr). Moreover, some residual saturation values are used in the context of various well enhancement procedures, such as residual oil saturation after waterflooding (Sorw) and residual oil saturation after gas flooding (Sorg).

Dynamic reservoir data may also include various relative permeability values. A relative permeability value may be a dimensionless term devised to adapt a Darcy equation to various multiphase flow conditions. Additionally, relative permeability data may correspond to a ratio of an effective permeability of a particular fluid at a particular saturation to an absolute permeability of that fluid at a total saturation. For example, a relative permeability may be 1.0 where only a single fluid is present in rock within a particular geological region. As such, a relative permeability may be based on a comparison of the abilities of different fluids to flow in the presence of each other within the geological region. Examples of relative permeabilities include relative gas permeability (Krg), relative water permeability (Krw), end-point relative oil permeability (Krog), and end-point relative water permeability Krow). For illustration, relative gas permeability may correspond to a fraction of gas in the presence of liquids (i.e., oil and water), while relative oil permeability may correspond a permeability of oil in the presence of gas and irreducible water.

One challenge present for reservoir simulations is to build a coarsened grid model that accurately captures reservoir heterogeneity while performing at minimal computational expense. To overcome this difficulty, upscaling techniques may be used to reduce the size of the grid model that performs the reservoir simulations. However, while upscaling techniques may operate effectively on static reservoir data, some techniques may have problems in accurately generating upscaled dynamic data, such as relative permeability and end-point saturations. Thus, some embodiments may implement an adaptive workflow that upscales reservoir properties based on integration of Lorenz upscaling methods and Coats upscaling methods (i.e., a vertical equilibrium method). As such, some embodiments may improve simulation runtime performance, provide quick assessments of simulation model uncertainty, reduce simulation computing costs, and provide optimization for simulation study durations.

Prior to performing a reservoir simulation, local grid refinement and coarsening (LGR) may be used to increase or decrease grid resolutions in various regions of a grid model. For example, various reservoir properties, e.g., permeability, porosity, or saturations, may correspond to discrete values that are associated with a particular grid cell or coarsened grid block. However, by using discrete values to represent a portion of a geological region, a discretization error may occur in a reservoir simulation. Thus, various fine-grid regions may reduce discretization errors as the numerical approximation of a finer grid is closer to the exact solution, however through a higher computational cost. As shown in FIG. 2B, for example, the coarsened grid model (290) may include various fine-grid regions (i.e., fine-grid region A (251), fine-grid region B (252)), that are surrounded by coarsened block regions. Likewise, the original grid model without any coarsening may be referred to as a fine-grid model.

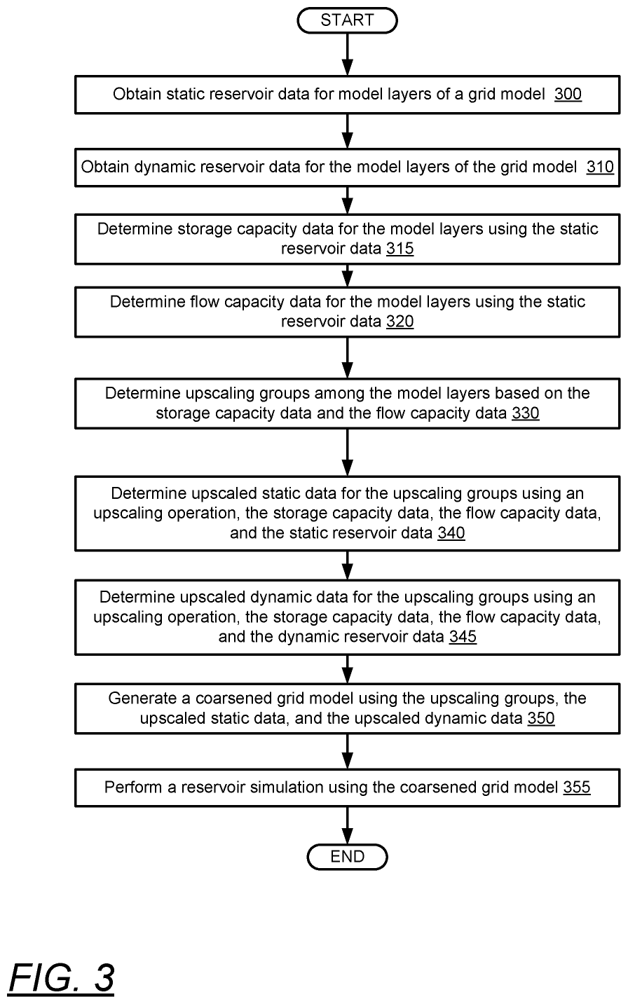

Turning to FIG. 3, FIG. 3 shows a flowchart in accordance with one or more embodiments. Specifically, FIG. 3 describes a general method for generating a coarsened grid model using upscaled dynamic data. One or more blocks in FIG. 3 may be performed by one or more components (e.g., reservoir simulator (160)) as described in FIGS. 1, 2A, 2B. While the various blocks in FIG. 3 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

In Block 300, static reservoir data are obtained for various model layers of a grid model in accordance with one or more embodiments. In particular, static reservoir data may be obtained from a fine-grid model (e.g., at a high resolution with millions of cells). For example, static reservoir data may include model cell thickness data, more porosity data, model permeability data, water saturation data, and/or net-to-gross (NTG) data. Moreover, the static reservoir data may be based on static reservoir properties described above in FIG. 2B and the accompanying description. The grid model may correspond to a geological region of interest (such as one or more reservoir regions) that may be a portion of a geological area or volume that includes one or more wells or formations of interest desired or selected for further analysis, e.g., for determining location of hydrocarbons or reservoir development purposes for a respective reservoir.

In Block 310, dynamic reservoir data are obtained for various model layers of a grid model in accordance with one or more embodiments. Dynamic reservoir data may include data regarding various end-point relative permeabilities and/or residual saturations (e.g., Swc, Sgr, Sorw, Sorg) for a geological region of interest within a grid model. Moreover, the dynamic reservoir data may be based on dynamic reservoir properties described above in FIG. 2B and the accompanying description.

In Block 315, storage capacity data are determined for various model layers using static reservoir data in accordance with one or more embodiments. For example, a storage capacity of a reservoir may be a function of porosity. Thus, storage capacity data may be determined by multiplying porosity values with cell thickness values (e.g., Phi×H) for cells within individual model layers of a grid model. Where a reservoir simulator determines average values for model cell thickness and porosity, the storage capacity may be then determined using a cumulative function based on a product of averaged porosity values and averaged model thickness values for each model layer.

In Block 320, flow capacity data are determined for various model layers using static reservoir data in accordance with one or more embodiments. For example, a flow capacity of a reservoir may be a function of permeability. Similar to storage capacity data, flow capacity data may be determined by multiplying static permeability values with cell thickness values (e.g., K×H) for cells within individual model layers of a grid model. Thus, a reservoir simulator may determine fluid capacity using a cumulative function based on a product of averaged permeability values and averaged model thickness values for each model layer.

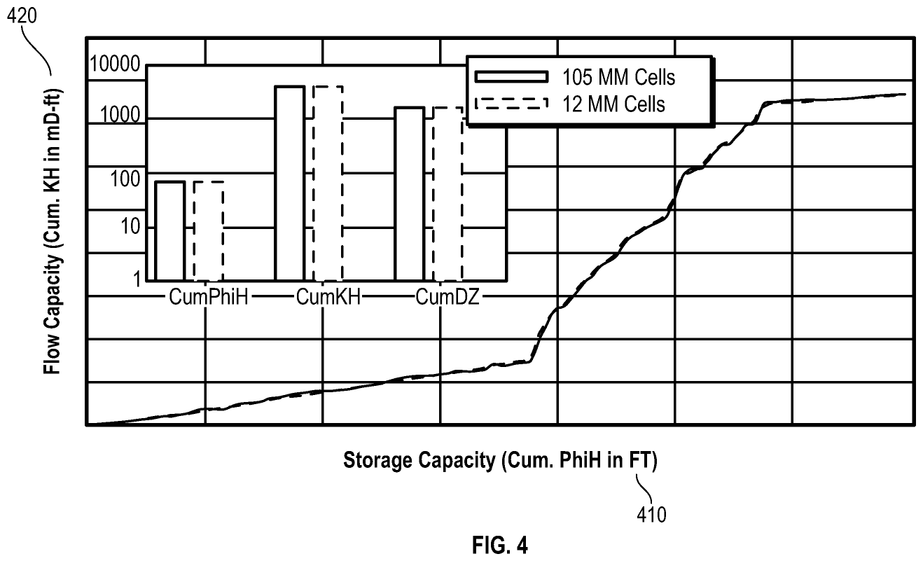

Turning to FIG. 4, FIG. 4 shows an example in accordance with one or more embodiments. As shown in FIG. 4, storage capacity (410) is illustrated in a horizontal axis and flow capacity (420) is illustrated in a vertical axis. Here, a plot shows storage capacity data and flow capacity data for a coarsened grid model and a fine-grid model.

Returning to FIG. 3, in Block 330, various upscaling groups are determined among various model layers based on storage capacity data and flow capacity data in accordance with one or more embodiments. In some embodiments, for example, various ratio values are determined between storage capacity and flow capacity in individual model layers. Based on these ratio values, different model layers may be assigned to different upscaling groups for later upscale processing. Furthermore, individual model layers with similar ratios may be organized to produce an upscaled layering based on one or more Lorenz plot of storage capacity data and/or flow capacity data.

In some embodiments, a reservoir simulator determines one or more Lorenz coefficients for upscaling operations. For example, a Lorenz coefficient may be defined in terms of a plot of a cumulative flow capacity versus a cumulative cell thickness. In other words, a Lorenz coefficient may be a simulation parameter that describes an amount of heterogeneity in a particular geological region of a grid model, such as different layers. In a Lorenz plot, for example, a Lorenz coefficient (L_{c}) may be a multiple of an area enclosed by a Lorenz curve within the Lorenz plot. Thus, the range of the Lorenz coefficient may be in a range of 0≤L_{c}≤1. For a homogeneous reservoir, the Lorenz coefficient may satisfy the equality L_{c}=0. With increasing reservoir heterogeneity, the value of the Lorenz coefficient L_{c} may subsequently increase, thereby producing Lorenz coefficient values in a range of 0.2≤L_{c}≤0.6. Thus, a reservoir simulator may use a Lorenz method to assess reservoir heterogeneity and upscale static reservoir properties accordingly. In some embodiments, static reservoir data is weighted based on one or more Lorenz coefficients.

In Block 340, upscaled static data are determined for various upscaling groups using an upscaling operation, storage capacity data, flow capacity data, and static reservoir data in accordance with one or more embodiments. For example, static reservoir data may be upscaled into a weighted average for an upscaling group using an upscaling operation. In other words, upscaling static data may provide upscaled layer values for model layers assigned to a respective upscaling group. The upscaling operation may be an operation or function that determines a Lorenz coefficient that is applied to static reservoir data. In some embodiments, for example, an upscaled water saturation value may be determined using the following equation:

S̅w̅=Σ_{Layer=1}^{Layer=n}Phi^{k}H^{k}Sw^{k}/Σ_{Layer=1}^{Layer=n}Phi^{k}H^{k} Equation 1

where S̅w̅ corresponds to upscaled water saturation data that is weighted based on the upscaling operation, k corresponds to a particular model layer within an upscaling group, Phi corresponds to a porosity value, H corresponds to a cell thickness value, n corresponds to the total number of model layers within the upscaling group, and Sw^{k} corresponds to a static water saturation value in the respective model layer k.

In Block 345, upscaled dynamic data are determined for various upscaling groups using an upscaling operation, storage capacity data, flow capacity data, and dynamic reservoir data in accordance with one or more embodiments. For determining upscaled dynamic data, the upscaling operation may be a Coats method, such as a vertical equilibrium method. As such, relative permeability values and end-point saturations values may be determined using pseudo functions. For example, a pseudo function may describe pseudo relative permeabilities based on absolute permeability values. Resulting pseudo functions may be used to weight upscaled data in an upscaling operation. In some embodiments, for example, a pseudo relative permeability for water may be determined using the following equation:

$${\overline{k}}_{rw} = \frac{{\int }_{o}^{h} {k}_{xy} ( z ) {k}_{rw} ( z ) dz}{{\int }_{o}^{h} {k}_{xy} ( z ) dz} \qquad Equation 2$$

where k̅_{rw} is the pseudo water relative permeability, k_{xy} is the absolute permeability for flow parallel to the x-y plane, k_{rw} is a water relative permeability, h is the reservoir thickness, d [symbol] is a layer thickness, and [symbol] is a depth value in the z direction. Likewise, other pseudo relative permeabilities are contemplated, such as pseudo gas relative permeability, pseudo end-point relative oil permeability, and pseudo end-point relative water permeability. Other pseudo relative permeabilities may be determined using similar equations such as Equation 2 for the respective reservoir property.

In Block 350, a coarsened grid model is generated using upscaled groups, upscaled static data, and upscaled dynamic data in accordance with one or more embodiments. By upscaling the reservoir properties of a grid model to achieve a coarsened grid model, a reservoir simulation may be performed with faster runtime and similar simulation results, such as in comparison to a fine-grid model.

In Block 355, a reservoir simulation is performed using a coarsened grid model in accordance with one or more embodiments. For example, a reservoir simulator may use grid model data from the coarsened grid model to solve well equations and reservoir equations in a particular simulation. By using a coarsened grid model, a reservoir simulator may reduce the total computation time for performing various types of simulations, such as history matching, predicting production rates at one or more wells, and/or determining the presence of hydrocarbon-producing formations for new wells. Likewise, various reservoir simulation applications may be performed, such as rankings, uncertainty analyses, sensitivity analyses, and/or well-by-well history matching. With respect to history matching, the objective may be to fit measured historical data to a reservoir model. In some embodiments, one or more reservoir simulations may optimize production for a well or group of wells, provide well design parameters for one or more wells, completion operations for one or more wells (e.g., using which down-hole devices).

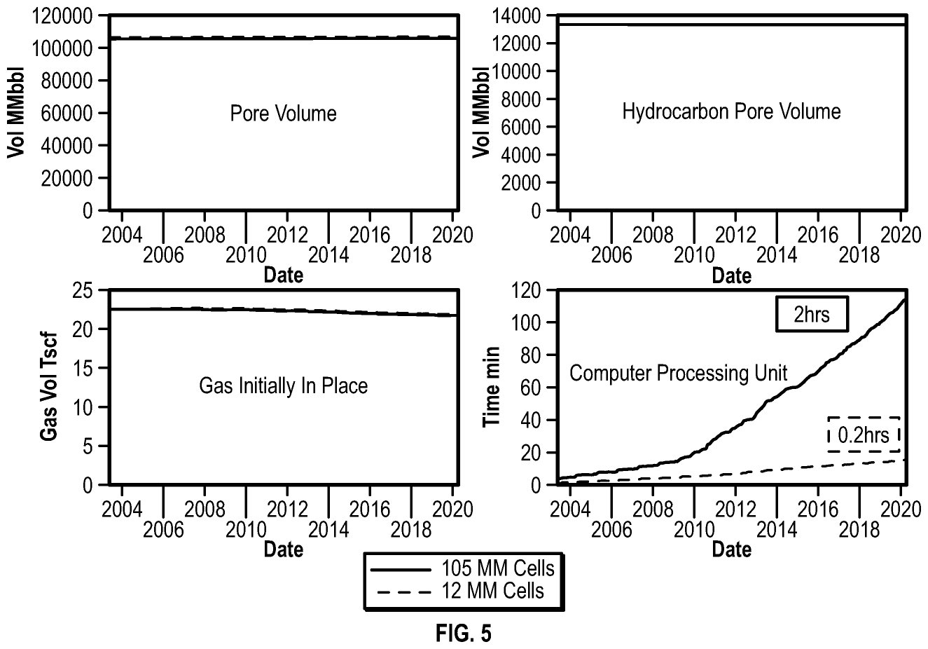

Turning to FIG. 5, FIG. 5 shows various comparison results in accordance with one or more embodiments. As shown in FIG. 5, fluid volumes (e.g., gas volume and oil volume) are illustrated with simulation run performance from some embodiments of an adaptive upscaling approach based on the process described in FIG. 3. In particular, reservoir simulations using different underlying systems are shown tested on a fine-grid model and a coarsened grid model. Here, simulation results are substantially identical between the fine-grid model and coarsened grid model with the added value of reducing the simulation runtime from two hours in the fine-grid model to 0.2 hrs in the coarsened grid model, i.e., by a factor of 10. More specifically, one graph illustrates differences in pore volume between the fine-grid model and a coarsened grid model. Another graph illustrates differences in hydrocarbon pore volume, and another graph illustrates differences in gas initially in place with the simulated reservoir region. While the differences between the fine-grid model and the coarsened grid model are relatively small, the coarsened grid model experiences significant computational gains as shown in the graph for the computer processing unit graph.

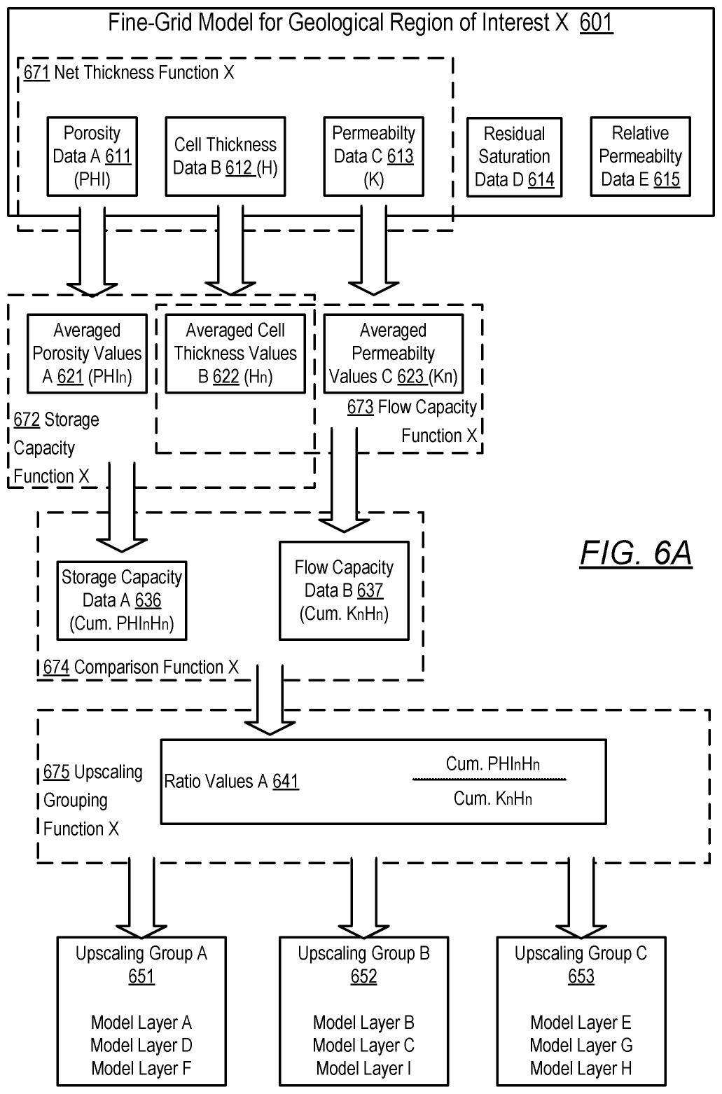

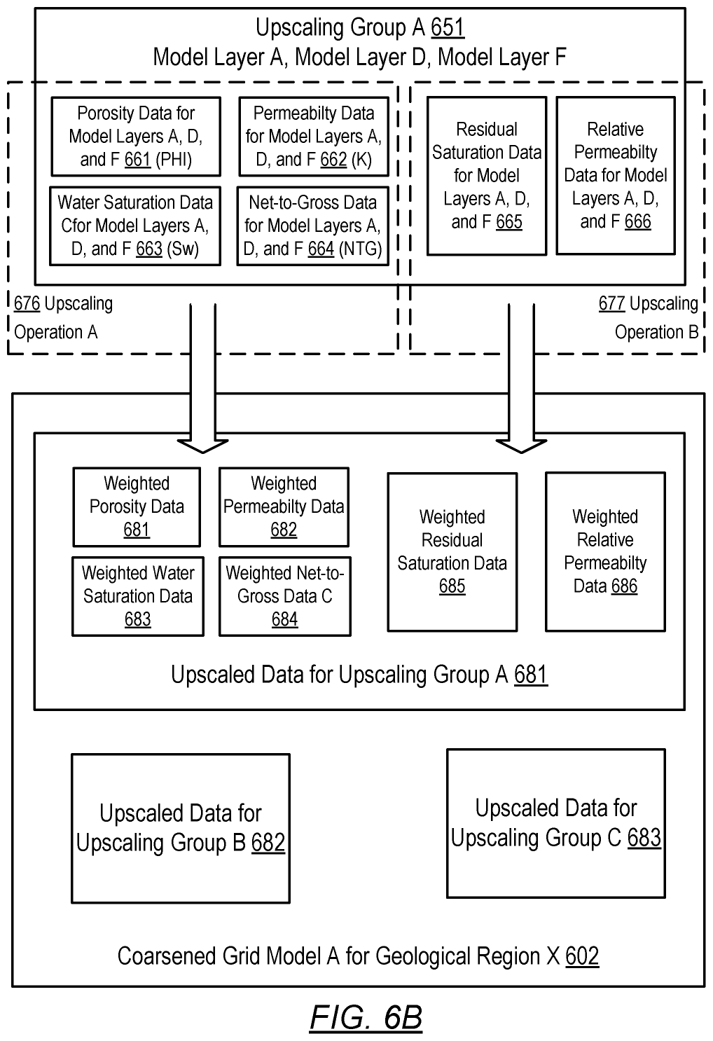

Turning to FIGS. 6A and 6B, FIGS. 6A and 6B provide an example of generating a coarsened grid model in accordance with one or more embodiments. The following example is for explanatory purposes only and not intended to limit the scope of the disclosed technology.

Turning to FIG. 6A, FIG. 6A illustrates a fine-grid model (601) for a geological region of interest X. The fine-grid model (601) includes various types of model data, i.e., porosity data A (611), cell thickness data B (612), permeability data C (613), residual saturation data D (614), relative permeability data E (615), and other types of model data not shown (e.g., NTG data). A reservoir simulator (not shown) applies a net thickness function X (671) to porosity data A (611), cell thickness data B (612), and permeability data (613), to determine averaged model data, i.e., averaged porosity values A (621), averaged cell thickness values B (622), and averaged permeability values C (623). Next, the reservoir simulator uses a storage capacity function X (672) on the averaged porosity values A (621) and the averaged cell thickness values (622) to determine storage capacity data A (636). The reservoir simulator also uses a flow capacity function X (673) on the averaged permeability values C (623) and the averaged cell thickness values B (622) to determine flow capacity data B (637).

Subsequently, the reservoir simulation determines ratio values A (641) using a comparison function X (674) with the storage capacity data A (636) and the flow capacity data B (637) as inputs to the function. Thus, the ratio values A (641) correspond to the ratio of storage capacity to flow capacity within the fine-grid model (601). Using the ratio values A (641) and an upscaling grouping function X (675), the reservoir simulator determines various upscaling groups, i.e., upscaling group A (651), upscaling group B (652), and upscaling group C (653). In particular, model layers A, D, and F are assigned to upscaling group A (651). Model layers B, C, and I are assigned to upscaling group B (652), while model layers E, G, and H are assigned to upscaling group C (653).

In FIG. 6B, a reservoir simulator uses the upscaling groups (651, 652, 653) to generate a coarsened grid model A (602) for the geological region X with upscaled data (681) for upscaling group A (651), upscaled data (682) for upscaling group B (652), and upscaled data (683) for upscaling group C (653). More specifically, the reservoir simulator applies an upscaling operation A (676), such as Lorenz method based on one or more Lorenz coefficients, to porosity data (661), permeability data (662), water saturation data (663), and net-to-gross data (664) for model layers A, D, and F. Here, upscaling operation A (676) is being used by the reservoir simulator to upscale static reservoir data from upscaling group A (651). On the other hand, the reservoir simulator applies an upscaling operation B (677) to dynamic reservoir data, i.e., residual saturation data (665) and relative permeability data (666) for model layers A, D, and F. For example, the upscaling operation B (677) may use pseudo functions to determined weighted upscaled data, e.g., in a similar manner as shown above in Equation 2. Accordingly, the coarsened grid model A (602) includes weighted porosity data (681), weighted permeability data (682), weighted water saturation data (683), and weighted net-to-gross data (684) generated from upscaling operation A (676), and weighted residual saturation data (685) and weighted relative permeability data (686) generated from upscaling operation B (677).

Embodiments may be implemented on a computer system. FIG. 7 is a block diagram of a computer system (702) used to provide computational functionalities associated with described algorithms, methods, functions, processes, flows, and procedures as described in the instant disclosure, according to an implementation. The illustrated computer (702) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (702) may include a computer that includes an input device, such as a keypad, keyboard, touch screen, or other device that can accept user information, and an output device that conveys information associated with the operation of the computer (702), including digital data, visual, or audio information (or a combination of information), or a GUI.

The computer (702) can serve in a role as a client, network component, a server, a database or other persistency, or any other component (or a combination of roles) of a computer system for performing the subject matter described in the instant disclosure. The illustrated computer (702) is communicably coupled with a network (730). In some implementations, one or more components of the computer (702) may be configured to operate within environments, including cloud-computing-based, local, global, or other environment (or a combination of environments).

At a high level, the computer (702) is an electronic computing device operable to receive, transmit, process, store, or manage data and information associated with the described subject matter. According to some implementations, the computer (702) may also include or be communicably coupled with an application server, e-mail server, web server, caching server, streaming data server, business intelligence (BI) server, or other server (or a combination of servers).

The computer (702) can receive requests over network (730) from a client application (for example, executing on another computer (702)) and responding to the received requests by processing the said requests in an appropriate software application. In addition, requests may also be sent to the computer (702) from internal users (for example, from a command console or by other appropriate access method), external or third-parties, other automated applications, as well as any other appropriate entities, individuals, systems, or computers.

Each of the components of the computer (702) can communicate using a system bus (703). In some implementations, any or all of the components of the computer (702), both hardware or software (or a combination of hardware and software), may interface with each other or the interface (704) (or a combination of both) over the system bus (703) using an application programming interface (API) (712) or a service layer (713) (or a combination of the API (712) and service layer (713). The API (712) may include specifications for routines, data structures, and object classes. The API (712) may be either computer-language independent or dependent and refer to a complete interface, a single function, or even a set of APIs. The service layer (713) provides software services to the computer (702) or other components (whether or not illustrated) that are communicably coupled to the computer (702). The functionality of the computer (702) may be accessible for all service consumers using this service layer. Software services, such as those provided by the service layer (713), provide reusable, defined business functionalities through a defined interface. For example, the interface may be software written in JAVA, C++, or other suitable language providing data in extensible markup language (XML) format or other suitable format. While illustrated as an integrated component of the computer (702), alternative implementations may illustrate the API (712) or the service layer (713) as stand-alone components in relation to other components of the computer (702) or other components (whether or not illustrated) that are communicably coupled to the computer (702). Moreover, any or all parts of the API (712) or the service layer (713) may be implemented as child or sub-modules of another software module, enterprise application, or hardware module without departing from the scope of this disclosure.

The computer (702) includes an interface (704). Although illustrated as a single interface (704) in FIG. 7, two or more interfaces (704) may be used according to particular needs, desires, or particular implementations of the computer (702). The interface (704) is used by the computer (702) for communicating with other systems in a distributed environment that are connected to the network (730). Generally, the interface (704 includes logic encoded in software or hardware (or a combination of software and hardware) and operable to communicate with the network (730). More specifically, the interface (704) may include software supporting one or more communication protocols associated with communications such that the network (730) or interface's hardware is operable to communicate physical signals within and outside of the illustrated computer (702).

The computer (702) includes at least one computer processor (705). Although illustrated as a single computer processor (705) in FIG. 7, two or more processors may be used according to particular needs, desires, or particular implementations of the computer (702). Generally, the computer processor (705) executes instructions and manipulates data to perform the operations of the computer (702) and any algorithms, methods, functions, processes, flows, and procedures as described in the instant disclosure.

The computer (702) also includes a memory (706) that holds data for the computer (702) or other components (or a combination of both) that can be connected to the network (730). For example, memory (706) can be a database storing data consistent with this disclosure. Although illustrated as a single memory (706) in FIG. 7, two or more memories may be used according to particular needs, desires, or particular implementations of the computer (702) and the described functionality. While memory (706) is illustrated as an integral component of the computer (702), in alternative implementations, memory (706) can be external to the computer (702).

The application (707) is an algorithmic software engine providing functionality according to particular needs, desires, or particular implementations of the computer (702), particularly with respect to functionality described in this disclosure. For example, application (707) can serve as one or more components, modules, applications, etc. Further, although illustrated as a single application (707), the application (707) may be implemented as multiple applications (707) on the computer (702). In addition, although illustrated as integral to the computer (702), in alternative implementations, the application (707) can be external to the computer (702).

There may be any number of computers (702) associated with, or external to, a computer system containing computer (702), each computer (702) communicating over network (730). Further, the term “client,” “user,” and other appropriate terminology may be used interchangeably as appropriate without departing from the scope of this disclosure. Moreover, this disclosure contemplates that many users may use one computer (702), or that one user may use multiple computers (702).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, any means-plus-function clauses are intended to cover the structures described herein as performing the recited function(s) and equivalents of those structures. Similarly, any step-plus-function clauses in the claims are intended to cover the acts described here as performing the recited function(s) and equivalents of those acts. It is the express intention of the applicant not to invoke 35 U.S.C. § 112(f) for any limitations of any of the claims herein, except for those in which the claim expressly uses the words “means for” or “step for” together with an associated function.

What is claimed:

1. A method, comprising:
obtaining, by a computer processor, static reservoir data for a grid model;
determining, by the computer processor and using the static reservoir data, dynamic reservoir data for the grid model;
determining, by the computer processor, a plurality of storage capacities and a plurality of flow capacities for a plurality of model layers within the grid model using the static reservoir data;
determining, by the computer processor, a plurality of upscaling groups among the plurality of model layers based on the plurality of flow capacities and the plurality of storage capacities;
generating, by the computer processor, upscaled static data using the plurality of upscaling groups, the static reservoir data, and the grid model;
generating, by the computer processor, upscaled dynamic data using the plurality of upscaling groups, the dynamic reservoir data, and the grid model; and
performing, by the computer processor, a reservoir simulation using a coarsened grid model comprising the upscaled static data and the upscaled dynamic data.

2. The method of claim 1, further comprising:
determining, by the computer processor, a Lorenz coefficient using a cumulative function, the plurality of flow capacities, and a plurality of model thickness values of the plurality of model layers,
wherein the Lorenz coefficient is a parameter that describes an amount of reservoir heterogeneity within a predetermined geological region of the grid model,
wherein the plurality of upscaling groups are determined using the Lorenz coefficient, and
wherein the upscaled static data is weighted data based on the Lorenz coefficient.

3. The method of claim 1, further comprising:
determining, by the computer processor, a plurality of pseudo relative permeability values for a fluid based on absolute permeability data for a predetermined flow of the fluid and relative permeability data for the fluid; and
determining, by the computer processor, a plurality of weighted saturation values for the fluid using a porosity weighting function and the static reservoir data,
wherein the upscaled dynamic data is based the plurality of pseudo relative permeability values and the plurality of weighted saturation values.

4. The method of claim 1, further comprising:
determining a plurality of ratio values between a plurality of storage capacities and a plurality of flow capacities,
wherein the plurality of upscaling groups are determined using the plurality of ratio values.

5. The method of claim 1,
wherein the static reservoir data comprise porosity data, permeability data, and water saturation data.

6. The method of claim 1,
wherein the dynamic reservoir data comprise a plurality of relative permeability values and a plurality of residual saturation values, and
wherein the plurality of relative permeability values correspond to a ratio of an effective permeability of a predetermined fluid at a predetermined saturation to an absolute permeability of the predetermined fluid at a total saturation.

7. The method of claim 1,
wherein the dynamic reservoir data comprise a plurality of residual saturation values, and
wherein the plurality of residual saturation values correspond to a plurality of ratio values of an effective porosity of a predetermined fluid to an amount of immobile fluid of the predetermined fluid in response to a displacement operation.

8. The method of claim 1, further comprising:
determining a predicted production rate for one or more wells in a geological region of interest using the reservoir simulation.

9. A system, comprising:
a wellhead coupled to a wellbore; and
a reservoir simulator comprising a computer processor and coupled to the wellhead,
wherein the reservoir simulator comprises functionality for:
obtaining static reservoir data for a grid model;
determining, using the static reservoir data, dynamic reservoir data for the grid model;
determining a plurality of storage capacities and a plurality of flow capacities for a plurality of model layers within the grid model using the static reservoir data;
determining a plurality of upscaling groups among the plurality of model layers based on the plurality of flow capacities and the plurality of storage capacities;
generating upscaled static data using the plurality of upscaling groups, the static reservoir data, and the grid model;
generating upscaled dynamic data using the plurality of upscaling groups, the dynamic reservoir data, and the grid model; and
performing a reservoir simulation using a coarsened grid model comprising the upscaled static data, the upscaled dynamic data, and wellhead data regarding the wellhead.

10. The system of claim 9, wherein the reservoir simulator further comprises functionality for:
determining a Lorenz coefficient using a cumulative function, the plurality of flow capacities, and a plurality of model thickness values of the plurality of model layers,
wherein the Lorenz coefficient is a parameter that describes an amount of reservoir heterogeneity within a predetermined geological region of the grid model,
wherein the plurality of upscaling groups are determined using the Lorenz coefficient, and
wherein the upscaled static data is weighted data based on the Lorenz coefficient.

11. The system of claim 9, wherein the reservoir simulator further comprises functionality for:
determining a plurality of pseudo relative permeability values for a fluid based on absolute permeability data for a predetermined flow of the fluid and relative permeability data for the fluid; and
determining, by the computer processor, a plurality of weighted saturation values for the fluid using a porosity weighting function and the static reservoir data,
wherein the upscaled dynamic data is based the plurality of pseudo relative permeability values and the plurality of weighted saturation values.

12. The system of claim 9, wherein the reservoir simulator further comprises functionality for:
determining a plurality of ratio values between a plurality of storage capacities and a plurality of flow capacities,
wherein the plurality of upscaling groups are determined using the plurality of ratio values.

13. The system of claim 9, wherein the reservoir simulator further comprises functionality for:
determining a predicted production rate for the wellhead using the reservoir simulation.

14. The system of claim 9,
wherein the dynamic reservoir data comprise a plurality of relative permeability values and a plurality of residual saturation values, and
wherein the plurality of relative permeability values correspond to a ratio of an effective permeability of a predetermined fluid at a predetermined saturation to an absolute permeability of the predetermined fluid at a total saturation.

15. The system of claim 9,
wherein the dynamic reservoir data comprise a plurality of residual saturation values, and
wherein the plurality of residual saturation values correspond to a plurality of ratio values of an effective porosity of a predetermined fluid to an amount of immobile fluid of the predetermined fluid in response to a displacement operation.

16. A non-transitory computer readable medium storing instructions executable by a computer processor, the instructions comprising functionality for:
obtaining static reservoir data for a grid model;
determining, using the static reservoir data, dynamic reservoir data for the grid model;
determining a plurality storage capacities and a plurality of flow capacities for a plurality of model layers within the grid model using the static reservoir data;
determining a plurality of upscaling groups among the plurality of model layers based on the plurality of flow capacities and the plurality of storage capacities;
generating upscaled static data using the plurality of upscaling groups, the static reservoir data, and the grid model;
generating upscaled dynamic data using the plurality of upscaling groups, the dynamic reservoir data, and the grid model; and
performing a reservoir simulation using a coarsened grid model comprising the upscaled static data and the upscaled dynamic data.

17. The non-transitory computer readable medium of claim 16, wherein the instructions further comprise functionality for:
determining a Lorenz coefficient using a cumulative function, the plurality of flow capacities, and a plurality of model thickness values of the plurality of model layers,
wherein the Lorenz coefficient is a parameter that describes an amount of reservoir heterogeneity within a predetermined geological region of the grid model,
wherein the plurality of upscaling groups are determined using the Lorenz coefficient, and
wherein the upscaled static data is weighted data based on the Lorenz coefficient.

18. The non-transitory computer readable medium of claim 16, wherein the instructions further comprise functionality for:
determining a plurality of pseudo relative permeability values for a fluid based on absolute permeability data for a predetermined flow of the fluid and relative permeability data for the fluid; and
determining, by the computer processor, a plurality of weighted saturation values for the fluid using a porosity weighting function and the static reservoir data,
wherein the upscaled dynamic data is based the plurality of pseudo relative permeability values and the plurality of weighted saturation values.

19. The non-transitory computer readable medium of claim 16, wherein the instructions further comprise functionality for:
determining a plurality of ratio values between a plurality of storage capacities and a plurality of flow capacities,
wherein the plurality of upscaling groups are determined using the plurality of ratio values.

20. The non-transitory computer readable medium of claim 16, wherein the instructions further comprise functionality for:
determining a predicted production rate for one or more wells in a geological region of interest using the reservoir simulation.
